(19) United States
(12) Patent Application Publication
(10) Pub. No.: US 2010/0092739 A1
(43) Pub. Date: Apr. 15, 2010

(54) COATING FOR MICROWAVABLE FOOD PRODUCT

(75) Inventors: Anton Kaasjager, Enschede (NL); Arjan Hovestad, 's-hertogenbosch (NL); Hein Jager, Borne (NL)

Correspondence Address: LUCAS & MERCANTI, LLP, 475 PARK AVENUE SOUTH, 15TH FLOOR, NEW YORK, NY, 10016, US

(73) Assignee: Nederlandse Organisatie voor toegepast-natuurweten schappelijk onderzoek TNO, Delft (NL)

(21) Appl. No.: 12/520,934

(22) PCT Filed: Dec. 21, 2007
(86) PCT No.: PCT/NL2007/050689

§ 371 Date: Jul. 30, 2009

(30) Foreign Application Priority Data
Dec. 29, 2006 (EP) 06077346.2

(51) Int. Cl. C23C 18/30; A41D 10/00; A41D 1/00; G01R 27/28; H01Q 1/36

(52) U.S. Cl. 428/209; 427/526; 427/525; 2/83; 2/114; 2/69; 324/654; 343/897

(57) ABSTRACT

The invention relates to an aqueous composition for preparing an edible coating on a microwavable food, which composition comprises at least one prolamin and at least one hydrocolloid or gelling agent. The invention further relates to a microwavable food comprising an edible coating, which coating comprises at least one prolamin and at least one hydrocolloid or gelling agent.

The invention is directed to a method for preparing a partly metallised fibrous web, to a partly metallised fibrous web and to the use thereof.

Metallised areas in fibrous webs, and in particular conductive areas in textiles, are of major interest for applications such as smart or intelligent textiles. In order to make a fibrous web conductive in a reliable way the conductive material should not only be present at the surface of the web but should also be there inside the web to a certain extent.

According to the state of the art, non-conductive fibrous webs can be made conductive by weaving a conductive yarn, such as silver yarn, into the web. This allows for instance to make conductive tracks through the fibrous web. Another possibility is to embroider conductive yarn into a non-conductive fibrous web. This allows the creation of certain predetermined conductive patterns. Although the conductive structure in itself is three dimensional the functional pattern is only two dimensional.

Further methods for making a non-conductive fibrous web conductive include for instance depositing a metal on the fibrous web by physical vapour deposition (PVD).

Disadvantages of the above-mentioned methods include the fact that weaving or embroidering a conductive yarn can result in a three dimensional structure in which the location of the conductive areas, in particular the depth of the area, is largely defined by the manufacturing process. Control over the exact location of the deposited metal particles by PVD is also limited. Further, some of the above-mentioned methods can only be carried out at specific moments in the manufacturing process of the, fibrous web. In addition, weaving conductive threads in the web limits the direction of the tracks to the weft and warp direction. The area of the web that can be reached with embroidery is usually limited and depends on the embroidery machine. As a result, the design of the final product is constrained. Further, due to mechanical restrictions on the yarns, which are suitable to be embroidered the conductivity and durability of the embroidered conductive fabrics are limited. There is a mismatch between the high cost of silver threads and the low cost of fabric. PVD needs to be done under vacuum conditions, which makes it difficult to adopt by the textile industry.

Another possibility for metallising a non-conductive surface is by electroless plating, also known as chemical or autocatalytic plating. This process uses an electrochemical reaction to deposit metal on an object without the passage of an external electric current. Electroless plating involves the deposition of a metal coating onto a substrate by immersing the substrate in a plating solution containing ions of the metal to be deposited and a chemical reducing agent. The metal ions are reduced by the chemical reducing agent in the plating solution, and deposit on the substrate. The metal ion and the reduction agent can be chosen such that the reaction needs a catalyst to start the chemical reaction. In this way metal ion and reducing agent can be part of the same plating solution in which the material with the catalyst is immersed. Metal is formed there where the catalyst is present. Once metal is formed the metal itself becomes the catalyst of the plating reaction. Metals that can thus be deposited include for instance gold, silver, copper, palladium, nickel, iron, and cobalt.

Electroless plating does not require electrical power. The plating volume and thickness can be controlled and readily varied. Further, electroless plating allows the formation of coatings with uniform thickness, even with irregularly shaped objects.

Parameters which influence the electroless plating process, besides the presence of a catalyst, include the concentration of chemicals, the pH of the plating solution, the amount and type of additives in the plating solution, the plating time and the plating temperature.

Metallising a fibrous web by electroless plating is for instance known from U.S. Pat. No. 5,599,585. A disadvantage of the method described in U.S. Pat. No. 5,599,585 is that by immersing the substrate into the plating solution the entire substrate will be uniformly coated. For certain applications it is desirable to metallise only part of the three dimensional structure of the fibrous web. U.S. Pat. No. In a study by Simor et al. (Surf. Coat. Technol. 2003, 172(1), 1-6) a polyester non-woven fabric was pre-treated with a nitrogen plasma and subsequently metallised with nickel. The catalyst in this study was applied from an aqueous bath. The aim of the plasma in this paper is to obtain a full coverage of the fabric, viz. full coverage of the fibres on the fabric surface. A full coverage is important for the object of the study, which is electromagnetic shielding. No distinction is made between the front and the back surface of the fabric. The study is silent with respect to local catalyst adsorption and possible catalyst penetration through the web.

WO-A-2005/087979 describes the application of a metal coating onto a flat non-fibrous polymer substrate in a pre-selected pattern. The metal coating is formed in a two-step procedure by reaction of a metal in a positive oxidation state applied in the first step with a reducing agent applied in a second step. According to this publication, plasma can be used to intensify the electrochemical reaction between the metal ion and the reducing agent resulting in a shorter process time. The plasma also causes chemical activation of the surface resulting in a better adhesion between the metal coating and the surface. This publication describes metallising of flat non-fibrous polymer substrates and not the metallisation of part of a fibrous web. This document is therefore not related to the specific problem faced when preparing conductive fibrous webs, namely that the conductive material should not only be present at the surface but also to a certain extent in the fibrous web in order to have a reliable conductive fibrous web.

The present inventors realised that a plasma can be used to control and define which part of the fabric will be metallised. By using a plasma to activate only part of the fibrous web, the catalyst will only adhere to that part of a fibrous web. As a result, only that part will be metallised. The plasma should be tailored to the surface to be activated and the catalysts.

Object of the invention is to provide a partly metallised fibrous web, in which one or more pre-determined parts (including parts within the fibrous web) have been metallised.

Further object of the invention is to provide a partly metallised fibrous web, with improved metallisation, preferably improved conductivity with respect to the prior art.

Another object of the invention is to provide a convenient and reliable method of metallising one or more pre-determined parts of a fibrous web.

In one aspect the invention is directed to a method for preparing a partly metallised fibrous web comprising:
subjecting one or more pre-determined parts of the fibrous web to a plasma treatment;
applying catalyst to at least the one or more plasma treated parts of the fibrous web; and
metallising the one or more pre-determined parts of the fibrous web by contacting at least the one or more pre-determined parts of the fibrous web with metal ions and a reducing agent.

The method of the invention is simple, quick and allows a control over various parameters. The plasma can be applied with a plasma torch. The catalyst can be applied on the fibrous web by conventional printing techniques. Adhesion of the catalyst to the fibrous web mainly takes place on the plasma treated part of the fibrous web. Non-adhered catalyst can be rinsed off. Subsequent metallising can for instance be performed by immersing the fibrous web with the catalyst in a solution containing metal ions and a reducing agent. The fibrous web can also be contacted with the metal ions and/or the reducing agent by conventional printing techniques. The plasma treated and subsequently catalyst covered part will selectively be metallised this way.

The term “plasma” as used in this application is meant to refer to a partially ionised gas that represents a chemically active environment, which consists of activated species such as electrons, ions, radicals, metastables and photons.

The term “fibrous web” as used in this application is meant to refer to a material made of any combination of cloth, yarn, fibre, or polymer. A fibrous web has a certain thickness so the surface and the volume of the web can be distinguished.

The expression “the surface of the fibrous web” in this context is meant to refer to the face of the web, i.e. the outer surface of the front or back of the fibrous web.

The term “part of the fibrous web” as used in this application is meant to refer to any part of the fibrous web, be it on the surface of the fibrous web (viz. the perpendicular projection of the web), or on the surface of fibrous within the volume of the fibrous web.

The term “cloth” as used in this application is meant to refer to a three dimensional structured material made from woven, braided or knitted yarns. In such a cloth the binding (i.e. the direction of the yarns, the way yarns intersect and the distance between the yarns) defines the structure (construction) of the fabric.

The term “non-woven” as used in this application is meant to refer to a non-structured material made from fibres.

The term “structured material” in this context is meant to refer to a fabric wherein the position and direction of the elements constructing the fabric, i.e. the fibres and yarns, are defined by the manufacturing process. Knowing the manufacturing process (weaving, knitting), the location of the yarns and fibres can be predicted. When detailed information about the manufacturing process is not available, a study of a random part of the structured fabric with sufficient size reveals the location of the fibres or yarns at any point of the fabric by a simple comparison.

The term “yarn” as used in this application is meant to refer to a continuous strand of fibres.

The term “fibre” as used in this application is meant to refer to a unit of matter, either natural, such as cotton, synthetic, such as polyester, or a combination thereof, which forms the basic element of, for example, non-wovens, cloth and yarns. A fibre itself may have a porous structure with voids.

Any type of plasma source may be used. Typical plasma sources include corona discharge, atmospheric pressure glow discharge, microwave discharge, volume filamentary dielectric barrier discharge, volume glow dielectric barrier discharge, plasma jet, micro hollow cathode discharge, surface dielectric barrier discharge, and diffuse coplanar surface barrier discharge. It is preferred that the plasma source is a pulsed plasma source, since this allows a better control over plasma conditions and chemistry.

Preferably, the plasma is applied with a plasma torch involving a plasma jet. The plasma treatment of the surface can comprise hydrogen abstraction, radical formation and/or introduction of new functional groups from the plasma environment. The plasma treatment results in a reactive activated surface. These changes of the chemical structure can be such that the surface tension is influenced resulting in a change of the wetting behaviour of the material. This way the plasma treatment becomes a tool to control the wetting properties of the web. Changing the plasma parameters will vary the geometry of the activated part of the web. The spot size of the plasma and thus the width and depth of the subsequent activated part of the web depend on the design of the plasma torch but can be in the range of 0.05-10 mm, preferably 0.1-5 mm. The penetration depth of the plasma depends mainly on the gas flow and the applied voltage. The fibrous web may be moved underneath the plasma torch or vice versa.

The plasma parameters can be chosen such that the catalyst is selectively attached to a first side of the fibrous web. The second side of the web can be metallised separately, for instance with a different metal or mixture of metals.

The application of two different metallic coatings on both. Sides of the fibrous web may be improved by applying a separating coating. This coating can be applied on the second side of the web, before or after one or more pre-determined parts on the first side have been metallised, but before one or more pre-determined parts on the second side of the web have been metallised. The coating may be a conventional coating and is for instance applied by a blade or a knife. The following materials can be used for these coatings: silicones, acrylates, polyurethanes, co-polymers, ethylene phenyl acetate, sol gel coatings and plasma deposited coatings. Preferably, the coating is a very thin coating, for example less than 100 nm, more preferably less than 5-50 nm, but it can be as broad and long as desirable. The coating and the plasma parameters can be tuned so that the wetting properties of the second side of the fibrous web when applying the second metal layer are such that the metal is selectively attached to the second side of the fibrous web, or at least more than readily than to the first side of the fibrous web.

According to the method of the invention, the catalyst can be applied by printing onto the fibrous web or can be applied by immersion in a bath containing the catalyst. Any catalyst may be used that is able to catalyse the reduction of the metal to be deposited in the metallising step. Examples of such catalysts include palladium, gold, silver, copper, tin, nickel, cobalt, iron, aluminium, zinc, molybdenum, tungsten, niobium, titanium, tantalum, ruthenium, and platinum.

Only a very small amount of catalyst is required. Typically, an amount of 0.1-100 mg/m², preferably 5-50 mg/m², for instance 10 mg/m² of catalyst is printed on the fibrous web.

Catalyst, which does not adhere to the web, can be easily rinsed off.

The plasma treated surface of the fibrous web with catalyst is contacted with metal ions and a reducing agent. This contacting can for instance comprise an immersion of the fibrous web in a plating solution, which comprises metal ions and a reducing agent. The plating solution is typically an aqueous solution. The reducing agent reduces the metal ions, which deposit on the surface when the oxidation number has reached zero. This metallising technique is known as electroless plating.

The metal ions and/or the reducing agent can also be printed onto the surface of the fibrous web, for example as a solution comprising the metal ions and the reducing agent, or as two separate solutions. Contacting the fibrous web with the metal ions and reducing agent by means of printing (such as inkjet printing) is preferred over immersing the fibrous web with the catalyst in a plating solution, because it allows a delicate control over the design. Further advantage of printing the metal ions and the reducing agent is that thereby the amount of unused chemicals, which have to be removed from the web after the metallisation process is finished, is limited. The amount of unused chemicals tends to be much greater for a web in comparison to for instance a foil due to the voids and capillaries present in the web. Removal is generally done by a rinsing step and wastewater treatment is therefore an important issue in processes like this.

The invention allows the catalyst to be present on and/or in one or more pre-determined parts of the fibrous web. These one or more pre-determined parts of the fibrous web provided with catalyst allow a local catalysis of the electrochemical metallisation reaction. The metal will selectively deposit at the pre-determined parts, which are provided with catalyst.

The catalyst, the metal ions and/or the reducing agent can be printed onto the surface of the fibrous web by conventional printing techniques, such as screen-printing, valve jet printing and inkjet printing. Preferably, the catalyst is printed by valve jet printing or inkjet printing.

Screen-printing involves a costly mask, the screen, which is absent in inkjet printing and the use of a valve jet. This makes the latter two techniques more flexible. It also means that there is no need for a repetitive design in the case of inkjet or valve jet printing. Computer Aided Manufacturing is easy to implement.

Screen-printing is done with pastes with a relatively high viscosity. The wetting of the fabric by these pastes will be more controlled by the viscosity than by the wetting properties of the surface of the fabric. The pastes with relatively high viscosity require specialised catalyst formulations that are more expensive and less effective. In inkjet printing standard catalyst formulations without modification can be used.

With a valve jet a larger amount of liquid is added to the substrate due to a bigger drop size, typically about 1 g of liquid on 1 g of fabric. With a piezo or bubble jet inkjet this relation is 10 to 100 times smaller, so 0.1. to 0.01 g liquid on 1 g of fabric.

In an embodiment of the invention, the printing technique is incorporated in the plasma. For example, the printing technique, preferably a valve jet or an inkjet, can be incorporated in a plasma torch.

Suitable metal ions to be used in accordance with the method of the invention are for example gold ions, silver ions, copper ions, nickel ions, tin ions, platinum ions, cobalt ions, palladium ions, iron ions and lead ions. It is also possible to apply a mixture of metal ions and then obtain a fibrous web with an alloy coating. Preferred metal ions are gold ions and, copper ions. Normally the metal ions are provided in the solution by dissolving a metal salt.

Typical electroless copper baths can be divided into two types: heavy deposition baths (designed to produce 2 to 5 μm of copper) and light deposition baths (designed to produce 0.50 to 1.00 μm of copper). The main constituents of typical electroless copper chemistry are sodium hydroxide, a reducing agent such as formaldehyde, ethylenediaminetetraacetic acid (EDTA) or another chelator, and a copper salt. In the complex reaction, which may be catalysed by palladium, the reducing agent reduces the copper ion to metallic copper. Formaldehyde (which is oxidised), sodium hydroxide (which is consumed), and copper (which is deposited) must be replenished frequently.

The reducing agent used in the plating solution or in the solution to be printed onto the surface of the fibrous web is preferably a mild reducing agent, such as formaldehyde, a formiate, dimethylaminoborane, diethylaminoborane, hydrazine, hypophosphite, or boron hydride.

The concentration of metal ions in the plating solution is in general 1-10 g/l. The concentration of the reducing agent is typically 1-50 ml/l. The ratio between the amount of applied metal ions to the amount of applied reducing agent can range from 0.1 to 2, preferably from 0.3 to 1. In case the metal ions and the reducing agents are provided in the same solution, the ratio between the concentration of metal ions and the concentration of reducing agents can range from 0.1 to 2, preferably from 0.3 to 1.

When the metal ions are applied by printing a metal solution onto the surface of the fibrous web, it is advantageous to use a high concentration of metal ions, such as a concentration of at least 10 g/l, preferably in the range of 25-75 g/l. A complexing agent (such as ammonia, gluconate, pyrophosphate, citrate and other polyvalent (in)organic salts) can be applied for obtaining such high concentrations. In addition, the use of a strong reducing agent such as dimethylaminoborane (DMAB) is advantageous in order to convert as many metal ions as possible to metal.

It is advantageous to stretch the fibrous web during the printing of the catalyst and during the metallising of the fibrous web. This facilitates the deposition process and increases the robustness of the resulting at least partly conductive fibrous web. Furthermore, the density of the conductive fibres in the fibrous web after relaxation is higher than the density of the conductive fibres when the deposition took place onto a non-stretched fibrous web.

The fibrous web can be a knitted or woven textile or a non-woven. Preferably, the fibrous web is a textile made from any combination of materials normally used in textiles, such as polyester, cotton, polyamide, polyacryl, wool, and silk.

The inventors further faced the problem that when catalysts, metal ions and reducing agents are printed on a fibrous web, such as cotton or polyester fibrous webs, the relative concentrations of the reactants depend on the surface tension of substrate and fluids due to migrations (spread) of the reactants over and in the fibrous web. For example, the spreading of a drop of the catalyst formulation may result in a concentration gradient of the catalyst over the surface and the depth of the fibrous web. Subsequent application of a drop of metal solution and a drop of reducing agent solution results in a concentric variation of the ratio between the different reactants. As a result, the metallising process will not be optimal in most parts of the web. In addition, the spreading behaviour of subsequent drops can be significantly different from the first drop, because the surface of the fibrous web is already wet. Moreover, subsequent application of different reactants in drops may lead to chromatographic effects in that some components spread easier than other components.

In case of a hydrophilic material the structured nature of these webs intensifies the migration of the chemicals due to capillary rise in the voids between fibres and yarns. This may lead to an uncontrolled metallisation of the web during electroless plating or to borders of patterns, which are not well-defined due to spread of the reactants. In the case of a hydrophobic fibrous web the chemicals do not spread sufficiently over the fibres thereby giving rise to conductivity problems because of insufficient conductive contact between the metallised fibres. This is especially problematic when than conductive tracks are to be constructed in the fibrous webs.

The quality of the metallisation depends strongly on the relative concentration. A high quality conductive metal grid is formed when the reduction reaction proceeds in an optimal way, which depends on the concentration of the reactants and the speed of the reaction. The speed can be influenced by the addition of an inhibitor and temperature. Under suboptimal conditions the metal will deposit in a chaotic way resulting in non-conductive stains. So it is very important that the migration or wetting proceeds in a controlled manner. This problem of uncontrolled metallisation or suboptimal metallisation due to migration of the reactants in the web has not previously been recognised.

The inventors surprisingly found that providing the fibrous web with a hydrophobic/hydrophilic pattern can control migration of the chemicals. Such a pattern may be provided on the fibrous web by alternative methods.

Accordingly, in a further aspect the invention is directed to a method for preparing a partly metallised fibrous web comprising
subjecting at least part of the surface of the fibrous web to a plasma treatment comprising an oxidative plasma atmosphere and/or at least part of the surface of the fibrous web to a plasma treatment comprising a reductive plasma atmosphere, thereby creating a hydrophobic/hydrophilic pattern on the surface of said fibrous web;
printing catalyst onto at least part of the plasma treated surface of the fibrous web; and
metallising at least part of the surface of the fibrous web by contacting the fibrous web with metal ions and a reducing agent.

A hydrophilic fibrous web can be subjected to a reductive plasma atmosphere, which renders at least part of the fibrous web hydrophobic, thereby creating a hydrophobic/hydrophilic pattern. A hydrophobic fibrous web can be subjected to an oxidative plasma atmosphere, which renders at least part of the fibrous web hydrophilic, thereby creating a hydrophobic/hydrophilic pattern. It is also possible to subject a fibrous web first to an oxidative plasma atmosphere and subsequently to a reductive plasma atmosphere or vice versa in order to create the hydrophobic/hydrophilic pattern on the surface of the fibrous web. Plasma treatment of the fibrous web can also be combined with the application of a hydrophilic and/or hydrophobic agent as discussed below.

An oxidative plasma atmosphere can be created by using one or more gases that are capable of plasma-induced covalent bonding of oxygen, thereby forming polar functional groups (such as carbonyls, carboxylics, and hydroxyls) on the surface of the fibrous web. Examples of such gases include O₂, N₂, N₂O, and CO₂.

A reductive plasma atmosphere can be created by using one or more gases that are capable of reducing oxides and/or organic moieties on the surface of the fibrous web. Examples of such gases include H₂, NH₃, CH₄ or CO.

The oxidative and/or reductive plasma gases may also comprise a neutral plasma gas, such as Ar, He or Ne.

It is also possible to create a hydrophilic/hydrophobic pattern by the application of a hydrophobic and/or hydrophilic agent onto at least part of the surface of the fibrous web. The agent can for example be comprised in a liquid or a gas. Hence, in a further aspect the invention is directed to a method for preparing a partly metallised fibrous web comprising
applying a hydrophobic agent and/or a hydrophilic agent onto at least part of the surface of a fibrous web, thereby creating a hydrophobic/hydrophilic pattern on the surface of the fibrous web;
printing catalyst onto at least part of the plasma treated surface of the fibrous web; and
metallising at least part of the surface of the fibrous web by contacting the fibrous web with metal ions and a reducing agent.

Suitable hydrophobic agents include paraffin wax, polysiloxane, fluorinated compounds, fattyacid modified resins, and organosilicates (such as methyltrimethoxy silane, methyltriethoxy silane, dimethyldimethoxy silane, and dimethyldiethoxy silane). Suitable hydrophilic agents include ethoxylated polyesters, sulphonated polyester and ethoxylated polyamides.

A hydrophilic/hydrophobic pattern can be created on a hydrophobic surface of a fibrous web by applying a hydrophilic agent. A hydrophilic/hydrophobic pattern can be created on a hydrophilic surface of a fibrous web by applying a hydrophobic agent. It is also possible to provide both a hydrophilic and a hydrophobic agent on the surface of the fibrous web. Furthermore, the application of a hydrophilic and/or hydrophobic agent may be combined with one or more plasma treatments of at least part of the surface of the fibrous web.

Agents comprised in a liquid can for instance be applied in a specific pattern by using conventional printing techniques. Advantageously, the surface of the fibrous web is dried after applying the hydrophobic and/or hydrophilic liquid and prior to printing the catalyst onto the surface of the fibrous web. Drying can for instance comprise an infrared heater or convective drying.

In a further embodiment of the invention, both front and back surface of the fibrous web are metallised with a different metal or mixture of metals. Since the invention allows to selectively metallise a pre-determined part of the fibrous web, it is possible to provide both front and back surface of the fibrous web with a different metal coating.

The invention is further directed to a partly metallised fibrous web which is obtainable by the inventive method. The spread of the catalyst through the fibrous web can be controlled by the plasma treatment (selective local metallisation by local plasma activation of the surface) and the hydrophilic/hydrophobic treatment (selective local metallisation by reduced migration of chemicals using a hydrophilic/hydrophobic pattern on the surface). This yields partly metallised fibrous webs, wherein one or more pre-determined parts of a fibrous web are much more accurately metallised than metallised fibrous web obtained by plating methods of the prior art. The partly metallised fibrous web of the invention can be used as a base to produce all kinds of devices on a fibrous web, including antennas, transmitters, solar cell, batteries, sensors etc.

Advantageously, the at least partly conductive fibrous web of the invention is used for instance in smart or intelligent textiles. The conductivity of the fibrous web is the result of the contact of different fibres in the fibrous web. The conductivity of such a structure changes upon stretching. This effect can be used to use the at least partly conductive fibrous web of the invention as an inductive or deformation sensor. Particularly interesting are the detection and monitoring of body activity, such as breathing, heart beat, posture and movement. For this use the at least partly conductive fibrous webs of the invention can be used as clothing, bedclothes etc.

Furthermore, conductive fibrous webs may be used for the integration of communication apparatuses (such as cell phones) and entertainment apparatuses (such as MP3 or MP4 players) in clothing. In this regard, the conductive metallic pattern can be used as an antenna, or wiring for receiving signals, or for the provision of power to a connected device.

The at least partly conductive fibrous web of the invention can also be used for manufacturing electrically heatable fibrous webs, such as bed sheets, blankets, furnishing fabrics and for clothing.

As used in clothing or bedclothes, the invention is especially applicable in sportswear and in medical appliances, both for acting as sensor or to apply heat to the body.

1. Method for preparing a partly metallised fibrous web comprising
subjecting one or more pre-determined parts of the fibrous web to a plasma treatment;
applying a catalyst to at least the one or more plasma treated parts of the fibrous web; and
metallising the one or more pre-determined parts of the fibrous web by contacting at least the one or more pre-determined parts of the fibrous web with metal ions and a reducing agent.

2. Method according to claim 1, wherein the catalyst is applied after the plasma treatment of the pre-determined part of the fibrous web.

3. Method according to claim 1, wherein the catalyst is applied simultaneously with the plasma treatment.

4. Method according to claim 1, wherein the catalyst is applied by a method selected from the group consisting of screen printing, valve jet printing and inkjet printing.

5. Method according to claim 1, wherein the catalyst is selected from the group consisting of palladium, gold, silver, copper, tin, nickel, cobalt, iron, aluminium, zinc, molybdenum, tungsten, niobium, titanium, tantalum, ruthenium, platinum, and mixtures thereof.

6. Method according to claim 1, wherein the metal ions are selected from the group consisting of gold ions, silver ions, copper ions, nickel ions, tin ions, platinum ions, cobalt ions, palladium ions, iron ions, lead ions, and mixtures thereof.

7. Method according to claim 1, wherein the reducing agent is selected from the group consisting of formaldehyde, a formiate, dimethylaminoborane, diethylaminoborane, hydrazine, hypophosphite, and boronhydride.

8. Method according to claim 1, wherein the plasma treatment comprises using a plasma torch.

9. Method according to claim 1, wherein the fibrous web is selected from the group consisting of a textile, a polymer web, a non-woven nanofibre, and a felt.

10. Method according to claim 1, wherein the fibrous web is a textile comprising a least one material selected from the group consisting of polyester, cotton, polyamide, polyacryl, wool, and silk.

11. Method according to claim 1, wherein pre-determined parts of a front surface and pre-determined parts of a back surface of the fibrous web are metallised with a different metal or different mixture of metals.

12. Method for preparing a partly metallised fibrous web comprising
subjecting at least part of the surface of the fibrous web to a plasma treatment comprising an oxidative plasma atmosphere and/or at least part of the surface of the fibrous web to a plasma treatment comprising a reductive plasma atmosphere, thereby creating a hydrophobic/hydrophilic pattern on the surface of said fibrous web;
printing catalyst onto at least part of the plasma treated surface of the fibrous web; and
metallising at least part of the surface of the fibrous web by contacting the fibrous web with metal ions and a reducing agent.

13. Method for preparing a partly metallised fibrous web, comprising:
applying a hydrophobic agent and/or a hydrophilic agent onto at least part of the surface of the fibrous web, thereby creating a hydrophobic/hydrophilic pattern on the surface of the fibrous web;
printing catalyst onto at least part of the plasma treated surface of the fibrous web; and
metallising at least part of the surface of the fibrous web by contacting the fibrous web with metal ions and a reducing agent.

14. Partly metallised fibrous web obtained by a method according to claim 1.

15. Partly metallised fibrous web according to claim 14, which fibrous web is partly electrically conductive.

16-18. (canceled)

19. Bedclothes comprising the at least partly conductive fibrous web according to claim 14.

20. Sportswear comprising the at least partly conductive fibrous web according to claim 14.

21. Medical appliance comprising the at least partly conductive fibrous web according to claim 14.

22. A deformation sensor or an inductive sensor comprising the at least partly metallised fibrous web according to claim 14.

23. Sportswear and medical appliances comprising the at least partly conductive fibrous web according to claim 14 as sensor or to apply heat to the body.

24. An antenna or wiring for a device comprising the at least partly conductive fibrous web according to claim 14.
